(19) United States
(12) Patent Application Publication
(10) Pub. No.: US 2017/0160406 A1
(43) Pub. Date: Jun. 8, 2017

(54) PHOTODETECTOR, AND CT DEVICE INCLUDING SAID PHOTODETECTOR

(71) Applicant: KABUSHIKI KAISHA TOSHIBA, TOKYO (JP)

(72) Inventors: KAZUYA MATSUZAWA, KAMAKURA (JP); SHOGO ITAI, KAWASAKI (JP); TAKAMITSU ISHIHARA, YOKOHAMA (JP)

(73) Assignee: KABUSHIKI KAISHA TOSHIBA, TOKYO (JP)

(21) Appl. No.: 15/434,700

(22) Filed: Feb. 16, 2017

Related U.S. Application Data
(63) Continuation of application No. PCT/JP2015/085971, filed on Dec. 24, 2015.

(30) Foreign Application Priority Data
Dec. 24, 2014 (JP) 2014-261362

(51) Int. Cl. G01T 1/20; H01L 31/107; H01L 27/146; G01T 1/208

(52) U.S. Cl. CPC G01T 1/2018; G01T 1/208; H01L 31/107; H01L 27/14663; H01L 27/14609

(57) ABSTRACT

A photodetector according to an embodiment includes; at least one photodiode including: a first electrode; an n-type semiconductor layer disposed on the first electrode; a first p-type semiconductor layer disposed above the n-type semiconductor layer, the first p-type semiconductor layer including a first surface region and a second surface region; a second p-type semiconductor layer disposed in the first surface region of the first p-type semiconductor layer, the second p-type semiconductor layer having a higher p-type impurity concentration than the first p-type semiconductor layer; and a second electrode disposed on the second surface region of the first p-type semiconductor layer and on the second p-type semiconductor layer.

### CROSS REFERENCE TO RELATED APPLICATIONS

This application is a continuation of International Application No. PCT/JP2015/085971, filed on Dec. 24, 2015, which is based upon and claims the benefit of priority from the prior Japanese Patent Application No. 2014-261362, filed on Dec. 24, 2014, the entire contents of which are incorporated herein by reference.

### FIELD

Embodiments of the present invention relate to photodetectors and CT devices including the photodetectors.

### BACKGROUND

At present, avalanche photodiodes are used as photodetection elements that detect weak optical signals. Such an avalanche photodiode includes: a pn junction at which a p-type layer disposed on the light receiving side is joined to an n-type layer disposed on the substrate side: an anode electrode connected to the p-type layer; and a cathode electrode connected to the n-type layer. If light enters when a reverse bias is applied between the anode electrode and the cathode electrode, the electrons of electron-hole pairs generated in a depletion layer flow into the n-type layer, and the holes flow into the p-type layer. Some of these electrons and holes collide with atoms in the depletion layer, and generate new electron-hole pairs. The electrons and holes generated in this manner further collide with other atoms, and further generate electron-hole pairs. This chain reaction is called an avalanche increasing effect to generate more electron-hole pairs than the electron-hole pairs generated from incident light.

After detecting light incidence, this avalanche photodiode returns to a standby state.

However, in a conventional avalanche photodiode, the holes generated by the avalanche increasing effect remain, and noise is caused by recoupling between the remaining holes.

### BRIEF DESCRIPTION OF THE DRAWINGS

FIG. 1 is a cross-sectional view of an avalanche photodiode that is used in a photodetector according to a first embodiment.

FIG. 2A is a diagram showing a hole concentration distribution in the avalanche photodiode of the first embodiment.

FIG. 2B is a diagram showing a hole concentration distribution in the avalanche photodiode of the first embodiment.

FIG. 3 is a diagram showing hole currents flowing in the anode electrodes in the first embodiment and a comparative example.

FIG. 4 is a diagram showing a potential distribution in the avalanche photodiode of the first embodiment.

FIG. 5 shows a circuit as a specific example of a photodetector according to the first embodiment.

FIG. 6 is a cross-sectional view of an avalanche photodiode that is used in a photodetector according to a second embodiment.

FIG. 7 is a cross-sectional view of an avalanche photodiode that is used in a photodetector according to a third embodiment.

FIG. 8 is a plan view of the cell array of avalanche photodiodes in a photodetector according to the third embodiment.

FIG. 9 is a block diagram showing the structure of a photodetector according to a fourth embodiment.

FIG. 10 is a block diagram showing the structure of a photodetector according to a fifth embodiment.

FIG. 11 is a schematic diagram of an exterior in a case where a photodetector of the fifth embodiment is used in a CT device.

### DETAILED DESCRIPTION

A photodetector according to an embodiment includes: at least one photodiode including: a first electrode; an n-type semiconductor layer disposed on the first electrode; a first p-type semiconductor layer disposed above the n-type semiconductor layer, the first p-type semiconductor layer including a first surface region and a second surface region; a second p-type semiconductor layer disposed in the first surface region of the first p-type semiconductor layer, the second p-type semiconductor layer having a higher p-type impurity concentration than the first p-type semiconductor layer; and a second electrode disposed on the second surface region of the first p-type semiconductor layer and on the second p-type semiconductor layer.

The following is a description of embodiments, with reference to the accompanying drawings.

### First Embodiment

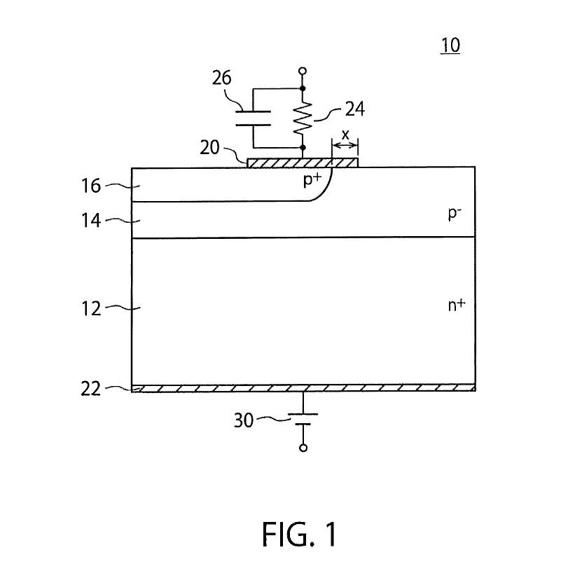

Referring to FIG. 1, a photodetector according to a first embodiment is described. The photodetector of this embodiment includes at least one avalanche photodiode (hereinafter also referred to as APD) 10 as a photodetection element, and FIG. 1 shows a cross-section of the APD 10.

This APD 10 includes: an n⁺-type layer 12; a p⁻type layer 14 that is disposed on the n⁺-type layer 12 and is joined to the n⁺-type layer 12; a p⁺-type layer 16 disposed in a surface region of the p⁻-type layer 14; an anode electrode 20 disposed over the p⁻-type layer 14 and the p⁺-type layer 16; a cathode electrode 22 disposed on the opposite side of the n⁺-type layer 12 from the p⁻-type layer 14; and a quench resistor 24 connected to the anode electrode 20. Of the anode electrode 20, the portion located on the p⁺¹-type layer 16 serves as a shunt electrode, and the portion located on the p⁻-type layer 14 serves as a Schottky electrode. The quench resistor 24 is connected to the shunt electrode. Meanwhile, a power supply 30 that applies a reverse bias to the APD 10 is connected to the cathode electrode 22. It should be noted that the n⁺-layer 12, the p⁻-type layer 14, and the p⁺-type layer 16 are made of silicon, for example.

In the APD 10, light enters from the side on which the anode electrode 20 is disposed. If the reverse bias to be applied to the APD 10 is made equal to or higher than the voltage at which an avalanche breakdown occurs (the breakdown voltage), the high electrical field of the reverse bias is applied between the anode electrode 20 and the cathode electrode 22. If light enters the APD 10 at this point, electron-hole pairs are generated in the depletion layer region to which the high electrical field is being applied. As a result, an avalanche breakdown is caused, and a high current flows. That is, electrical discharge starts. The high current that flows at this time generates saturation power inherent to the APD 10 or power corresponding to incidence of one photon, regardless of the quantity of light that enters the APD 10. That is, the APD 10 can detect one photon. In this APD 10, large power can also be obtained through a discharge phenomenon when one photon is detected. Once electrical discharge starts, the electrical discharge continues while the electrical field inside the APD 10 (the electrical field formed with the reverse bias) is maintained.

After detecting a photon, the APD 10 suspends the electrical discharge, and detects the next photon. To suspend the electrical discharge and lower the operating voltage, the quench resistor 24 is connected to the anode electrode 20. That is, when the above electrical discharge occurs, a high current flows through the quench resistor, and the voltage drop caused by the quench resistor terminates the amplification effect. As will be described later, the quench resistor 24 is disposed around the active region of the APD 10 (or around the p⁻-layer 14 and the p⁺-type layer 16, for example). A quench capacitance 26 is generated as the parasitic capacitance generated because of the setting of the quench resistor 24.

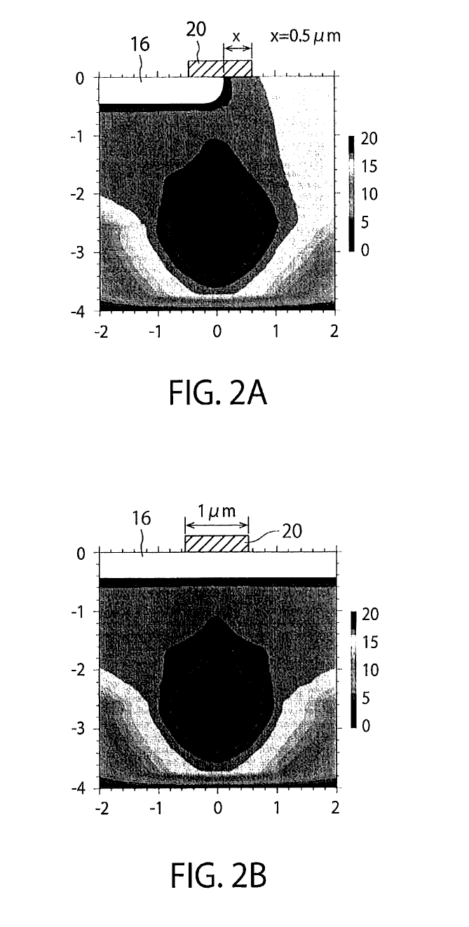

Referring now to FIGS. 2A through 4, holes that can be prevented from remaining after electrical discharge in the APD 10 used in this embodiment are described.

First, in the APD 10 used in the first embodiment shown in FIG. 1, the length X of the Schottky electrode portion of the anode electrode 20 was set at 0.5 μm, a reverse bias of 65 V was applied to the APD 10 from the power supply voltage 30, and the hole concentration distribution at the pn junction of the APD 10 after 50 ps since the electrical discharge was determined through simulations. FIG. 2A shows the results of the simulations. As a comparative example, the same simulations were performed on an APD that differs from the APD 10 shown in FIG. 1 in that the p⁺-layer 16 was formed on the entire upper surface of the p⁻-layer 14. FIG. 2B shows the results of the simulations. The APD of this comparative example differs from the APD 10 of the first embodiment in that any Schottky electrode portion does not exist in the anode electrode, and the APD is a conventional pn diode. In this comparative example, the length of the anode electrode was 1 μm.

As can be seen from FIGS. 2A and 2B, the amount of holes decreases by a larger amount in the APD 10 of this embodiment than in the APD of the comparative example. Particularly, the amount of holes decreases on the side on which the Schottky electrode is disposed.

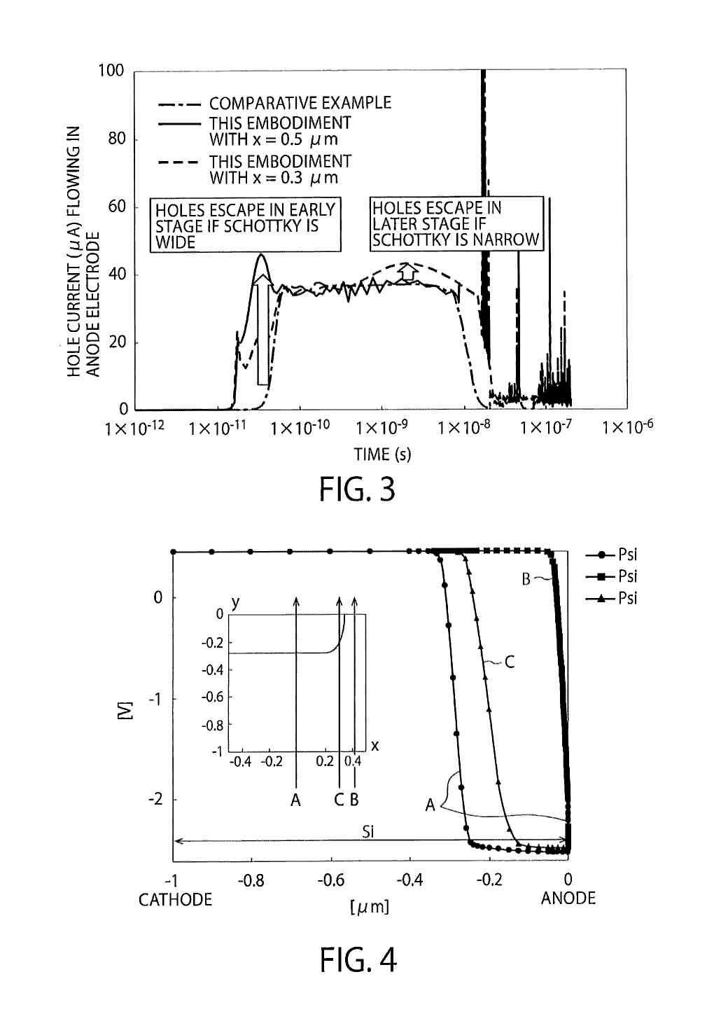

Also, a reverse bias of 65 V was applied to the APD of the comparative example, and to APDs 10 of this embodiment in which the lengths X of the Schottky electrode portions were 0.5 μm and 0.3 μm respectively. The passing of the hole current (μA) flowing in each anode electrode was determined through simulations. FIG. 3 shows the results of the simulations. The hole current in the APD of the comparative example is indicated by a dot-and-dash line, the hole current in the APD 10 in which the length X of the Schottky electrode portion is 0.5 μm is indicated by a solid line, and the hole current in the APD 10 in which the length X of the Schottky electrode portion is 0.3 μm is indicated by a broken line.

As can be seen from FIG. 3, the hole current in each APD 10 of this embodiment is higher than that in the APD of the comparative example. This indicates that, as the Schottky electrode portion is formed in the anode electrode as in this embodiment, holes flow from the anode electrode.

Also, where the length X of the Schottky electrode portion of the anode electrode is long, or the Schottky electrode portion is wide, holes flow out of the APD 10 in an early stage. Where the Schottky electrode portion is narrow, holes flow out of the APD 10 in a later stage.

There is an upper limit to the length X of each Schottky electrode portion. As can be seen from FIG. 1, the length X of the Schottky electrode portion is the distance between the end of the anode electrode 20 on the Schottky electrode side and the p⁺-type layer 16, and this length X is equal to or smaller than the extent Xmax of the depletion layer formed at the junction between the p⁻-type layer 14 and the p⁺-type layer 16. This extent Xmax can be expressed by the equations shown below (see JP 4024954 B2).

Xmax={2×εq×(Na+Nd)/(Na/Nd×Vbi+Vd)}^{1/2}

Vbi=k×T/q×In(Na×Nd/nₗ²)

Here, ε represents the permittivity of the substrate (p⁻-type layer 14), q represents the unit elementary charge, Na represents the concentration in the substrate (p⁻-type layer 14), Nd represents the maximum concentration in the p⁺-type layer 16, Vbi represents the built-in voltage, T represents the absolute temperature, nₗ represents the intrinsic carrier concentration, and k represents the Boltzmann constant.

Next, in an APD 10 of this embodiment, the potential distribution in the direction of depth of the substrate was determined through simulations where the potential of the anode electrode 20 was −2 V. FIG. 4 shows the results of the simulations.

As can be seen from FIG. 4, in a cross-section indicating the pn junction, there is hardly a potential gradient in the p⁺-type layer 16, and the excess holes generated due to the avalanche breakdown are absorbed by the anode electrode 20 through thermal diffusion. In a cross-section B indicating the Schottky junction, on the other hand, the p⁺-type layer 16 does not exist, and accordingly, the potential distribution is such that holes can quickly reach the anode electrode. The cross-section C indicating the junction between the p⁻-type layer 14 and the p⁺-type layer 16 is the potential distribution between the cross-section A and the cross-section B.

As is apparent from the above description, an APD 10 of this embodiment can reduce the remaining holes among the holes generated by an avalanche increasing effect. To reduce the remaining holes, the p⁺-type layer 16 preferably has an impurity concentration of 1×10¹⁹ cm⁻³ or higher. Meanwhile, the p⁻-type layer 14 preferably has an impurity concentration not lower than 1×10¹⁷ cm⁻³ but lower than 1×10¹⁹ cm⁻³.

According to the above description, the remaining holes can be reduced in an operation after electrical discharge, or noise due to the remaining holes can be reduced. However, not only after electrical discharge but also during electrical discharge and in a standby state, the noise due to the remaining holes can be reduced. It should be noted that, in a standby state, slowly diffused holes might be the source of noise. However, with an APD 10 of this embodiment, the remaining holes can be reduced even in a standby state, and the noise due to the holes can be reduced.

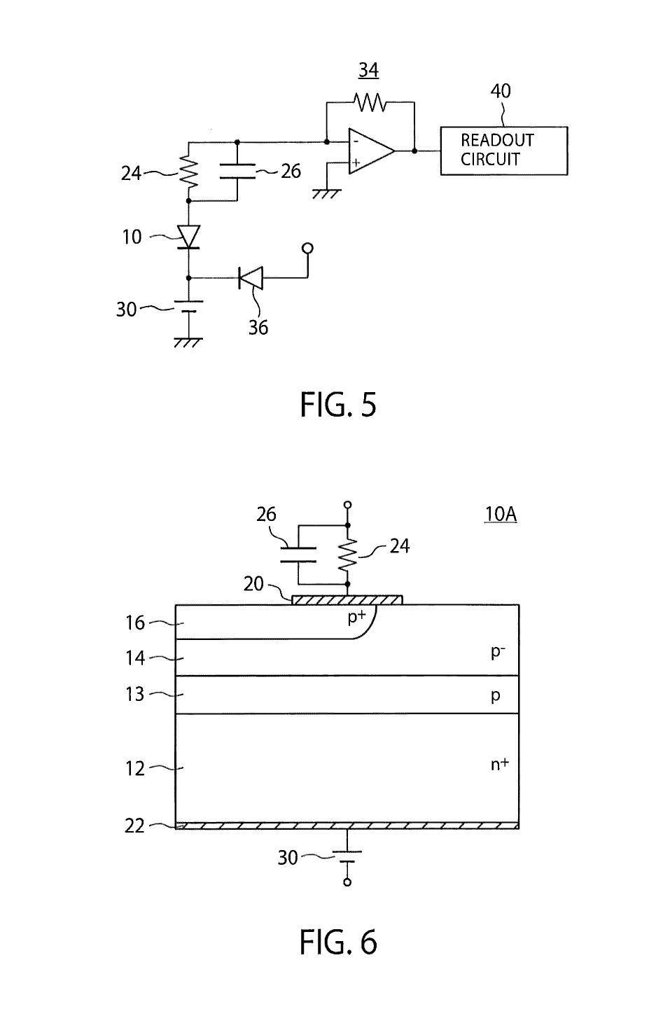

FIG. 5 shows a specific example of the circuit of a photodetector according to this embodiment. In the circuit of this specific example, the quench resistor 24 and the quench capacitance 26 are connected in parallel to the anode electrode side of the APD 10 shown in FIG. 1, and the input terminal of an operational amplifier 34 is connected to the quench resistor 24. A readout circuit 40 is connected to the output terminal of the operational amplifier 34. On the other hand, the power supply voltage 30 and an overvoltage protection circuit 36 are connected to the cathode electrode side of the APD 10.

In a photodetector having such a structure, a signal detected by the APD 10 to which a reverse bias is being applied is sent to the operational amplifier 34 via the quench resistor, and is amplified. The amplified signal is read out by the readout circuit 40, and thus, the photodetection is completed.

In a photodetector of this embodiment, the power supply 30 is connected to the cathode electrode side of the APD 10, and the operational amplifier 34 is connected to the anode electrode side, as shown in FIG. 5, However, the power supply voltage 30 may be connected to the anode electrode side of the APD 10, and the operational amplifier 34 may be connected to the cathode electrode side. In a case where the power supply voltage 30 is connected to the anode electrode side of the APD 10, the overvoltage protection circuit 36 is preferably also connected to the anode electrode side.

As described above, according to the first embodiment, remaining holes among the holes generated by an avalanche increasing effect can be reduced. Thus, a hole current can be accurately detected.

### Second Embodiment

Referring now to FIG. 6, a photodetector according to a second embodiment is described. The photodetector of the second embodiment has the same structure as the photodetector of the first embodiment, except that the APD 10 shown in FIG. 1 is replaced with an APD 10A shown in FIG. 6. This APD 10A has the same structure as the APD 10 shown in FIG. 1, except that a p-type layer 13 is disposed between the n⁺-type layer 12 and the p⁻-type layer 14. As this p-type layer 13 is disposed, the degree of freedom in designing the potential gradient to be caused between the anode electrode 20 and the cathode electrode 22 of the APD 10A can be increased, and the remaining holes can be further reduced.

Like the first embodiment, the second embodiment can also reduce remaining holes among the holes generated by an avalanche increasing effect. Thus, a hole current can be accurately detected.

### Third Embodiment

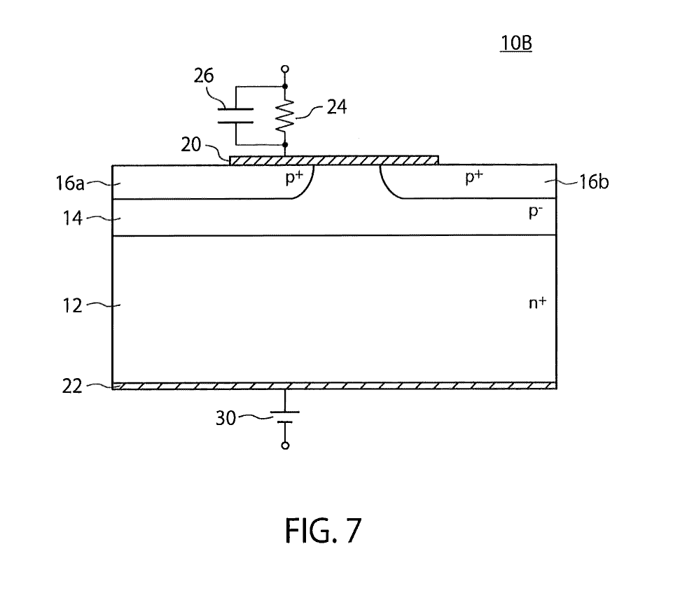

Referring now to FIG. 7, a photodetector according to a third embodiment is described. The photodetector of the third embodiment has the same structure as the photodetector of the first embodiment, except that the APD 10 shown in FIG. 1 is replaced with an APD 10B shown in FIG. 7. This APD 10B has the same structure as the APD 10 shown in FIG. 1, except that p⁺-type layers 16a and 16b are disposed on both sides of the anode electrode 20. The p⁺-type layer 16a and the p⁺-type layer 16b are disposed at a distance from each other in a surface region of the p⁻-type layer 14, and the portion of the anode electrode 20 located on the p⁻-type layer 14 between the p⁺-type layer 16a and the p⁺-type layer 16b serves as a Schottky electrode.

As a modification of the third embodiment, two p⁺-type layers may be disposed on both sides of the anode electrode 20 of the APD 10A shown in FIG. 6, as in the case shown in FIG. 7.

Like the first embodiment, the third embodiment and its modification can also reduce remaining holes among the holes generated by an avalanche increasing effect. Thus, a hole current can be accurately detected.

### Fourth Embodiment

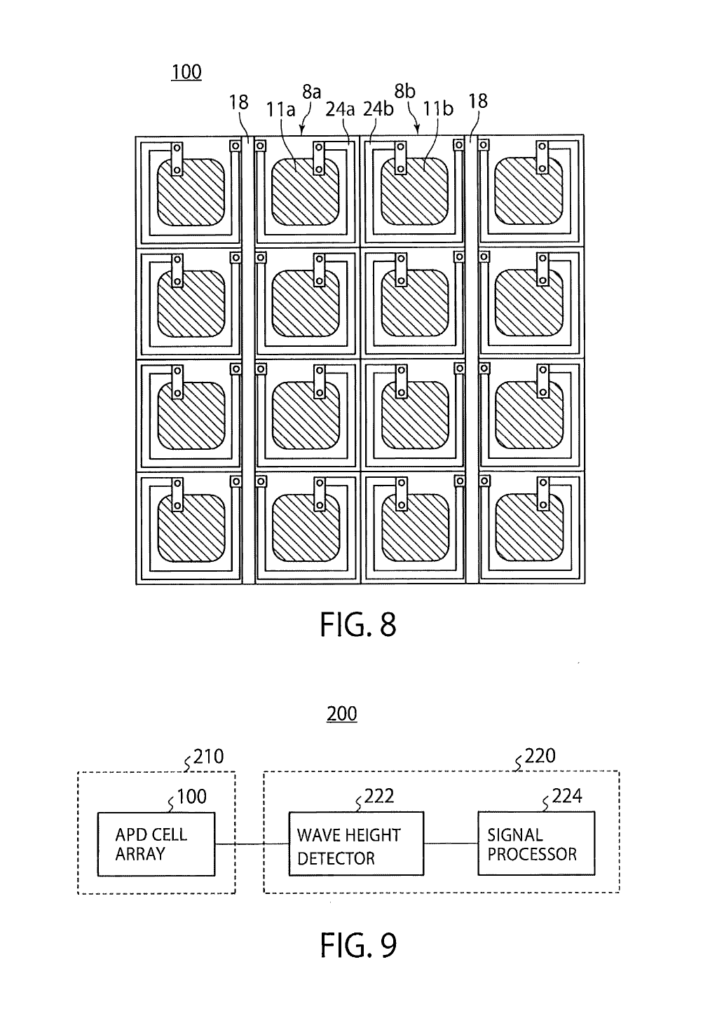

Referring now to FIGS. 8 and 9, a photodetector according to a fourth embodiment is described. The photodetector of the fourth embodiment has a structure in which cells containing APDs used in one of the first through third embodiment and the modification, or cells containing the APDs 10, for example, are arranged in an array. FIG. 8 is a plan view of the APD cell array used in the fourth embodiment.

In this APD cell array 100, two APD cells 8a and 8b form a pair, and the pairs are arranged in an array. An APD cell 8a includes an APD 10 having an APD active region 11a, and a quench resistor 24a for restricting the current to be output from the APD 10. An APD cell 8b includes an APD 10 having an APD active region 11b, and a quench resistor 24b for restricting the current to be output from the APD 10. It should be noted that the quench resistors 24a and 24b are formed with polysilicon, for example.

The APD cells 8a and 8b of each pair are arranged adjacent to each other in the row direction. A wiring line 18 extending in the column direction is disposed between each two pairs adjacent to each other in the row direction. That is, wiring lines 18 are disposed on both sides of each pair in the row direction, and a wiring line 18 is shared among the pairs arranged in the same column. In FIG. 8, an APD cell 8a is disposed on the left side of one pair in the row direction, and an APD cell 8b is disposed on the right side of the pair, for example. The quench resistor 24a of a pair is connected to the active region 11a and the wiring line 18 disposed on the left side of the pair, and surrounds three sides of the active region 11a. The quench resistor 24b of the pair is connected to the active region 11b and the wiring line 18 disposed on the right side of the pair, and surrounds three sides of the active region 11b. Because of this, in the APD cells 8a and 8b that form a pair and are adjacent to each other, the quench resistor 24a and the quench resistor 24b are symmetry with respect to a line extending in the column direction.

FIG. 9 shows the structure of the photodetector of the fourth embodiment. The photodetector 200 of this embodiment includes a photodetection circuit 210 and a signal processing circuit 220. The photodetection unit 210 includes the APD cell array 100 shown in FIG. 8. A photon that enters the photodetection circuit 210 is converted into an electrical signal by the APD cell array 100. The electrical signal photoelectrically converted by the photodetection circuit 210 is processed by the signal processing circuit 220, and a check is made to determine whether a photon has been detected.

The signal processing circuit 220 includes a wave height detector 222 that converts an analog electrical signal output from the APD cell array 100 into a digital signal, and a signal processor 224 that processes the digital signal converted by the wave height detector 222. Although the signal processing circuit 220 also includes circuits related to driving and the characteristics of the photodetector, such as a power supply circuit and a temperature compensation control circuit, these circuits are not shown in the drawing, for ease of explanation of this embodiment. Although the wave height detector 222 is included in the signal processing circuit 220 for ease of explanation, the wave height detector 222 may be formed as an on-chip circuit on the same chip as that of the APD cell array 100 formed with a semiconductor substrate. It should be noted that an output signal subjected to digital signal processing at the signal processor 224 may be transferred to an information terminal such as a PC via a USB cable, for example.

Like the first embodiment, the fourth embodiment can also reduce remaining holes among the holes generated by an avalanche increasing effect. Thus, a hole current can be accurately detected.

### Fifth Embodiment

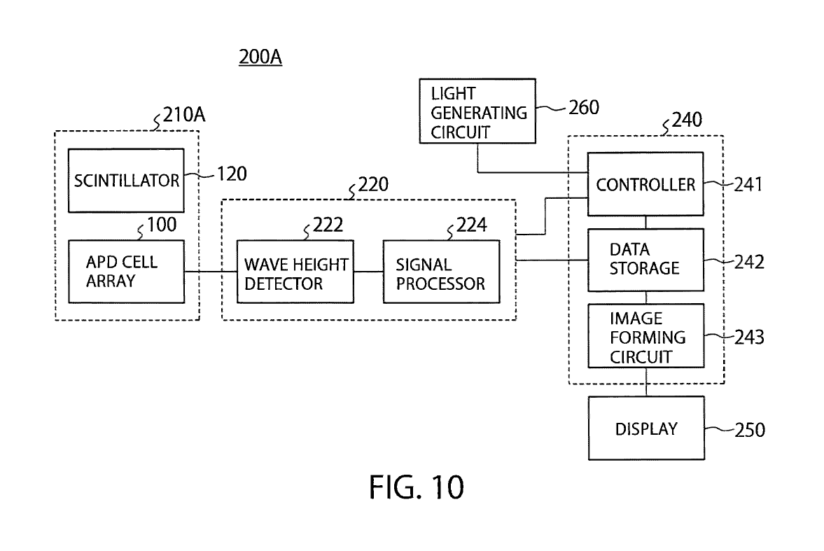

FIG. 10 shows a photodetector according to a fifth embodiment. The photodetector 200A of the fifth embodiment includes: a light generating circuit 260 that generates a photon to be measured; a photodetection circuit 210A that detects the photon and converts the photon into an electrical signal; a signal processing circuit 220 that processes the electrical signal photoelectrically converted by the photodetection circuit 210A: and a control circuit 240 that has the functions to analyze the data of the signal output from the signal processing circuit 220, and control the light generating circuit 260 and the photodetector 200A.

In a case where the wavelength of light emitted from the light generating circuit 260 is within a radiation region, the photodetection circuit 210A includes: a scintillator 120 that emits fluorescence from radiation; and an APD cell array 100 that detects the fluorescence generated by the scintillator 120, as shown in FIG. 10.

In the photodetector 200A according to the fifth embodiment, the control circuit 240 uses a controller 241 to control the timing of generation of light energy generated from the light generating circuit 260, and control the signal processing circuit 220. In this manner, synchronization with the output from the photodetection circuit 210A is achieved. The analog electrical signal output from the APD cell array 100 is input to the wave height detector 222 of the signal processing circuit 220, and is converted into a digital signal. The digital signal is then input to the signal processor 224. In the signal processor 224, the digital signal is analyzed by the wave height detector 222, and, if the signal exceeds a threshold value, the signal is recorded and is output.

The signal output from the signal processor 224 is recorded and saved in a data storage 242 in the control circuit 240. An image forming circuit 243 forms an image in accordance with the data stored in the data storage 242, and the formed image is displayed on a display 250.

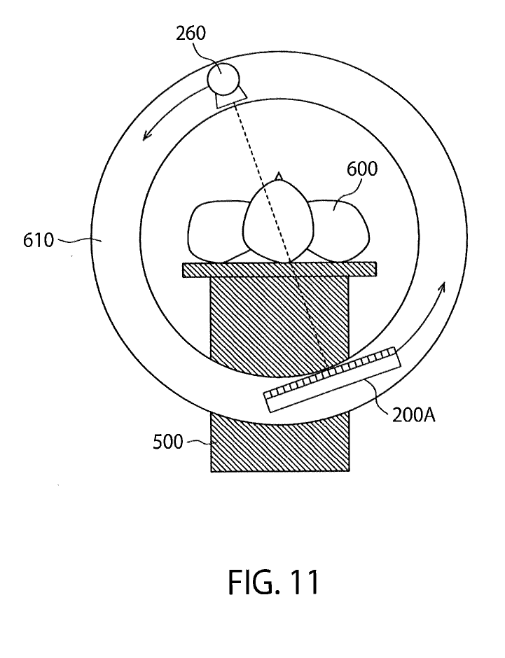

An example application of the photodetector 200A of the fifth embodiment is a computed tomography (CT) device for medical image diagnosis. FIG. 11 is a schematic diagram of an exterior in a case where the photodetector 200A of the fifth embodiment is used in a CT device. The light generating circuit 260 and the photodetector 200A are attached to the opposite sides of a gantry 610. Radiation emitted from the light generating circuit 260 passes through the inside of the body of a subject 600 lying on a bed 500, and is detected by the photodetector 200A. While the radiation passes through the inside of the body of the subject 600, photons are transmitted or absorbed by the substance in the body. Therefore, only the radiation energy absorbed by the substance in the body has a lowered frequency in the output signal histogram. This is then subjected to image formation processing, so that the substance in the body is discriminated, and the positional relationship becomes clear.

Like the fourth embodiment, the fifth embodiment can also reduce remaining holes among the holes generated by an avalanche increasing effect. Thus, a hole current can be accurately detected, and an image with higher precision can be obtained.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A photodetector comprising
at least one photodiode including: a first electrode; an n-type semiconductor layer disposed on the first electrode; a first p-type semiconductor layer disposed above the n-type semiconductor layer, the first p-type semiconductor layer including a first surface region and a second surface region; a second p-type semiconductor layer disposed in the first surface region of the first p-type semiconductor layer, the second p-type semiconductor layer having a higher p-type impurity concentration than the first p-type semiconductor layer; and a second electrode disposed on the second surface region of the first p-type semiconductor layer and on the second p-type semiconductor layer.

2. The photodetector according to claim 1, wherein the photodiode is an avalanche photodiode.

3. The photodetector according to claim 1, further comprising
a third p-type semiconductor layer disposed between the n-type semiconductor layer and the first p-type semiconductor layer, the third p-type semiconductor layer having a lower p-type impurity concentration than the second p-type semiconductor layer and having a higher p-type impurity concentration than the first p-type semiconductor layer.

4. The photodetector according to claim 1, wherein:
the first p-type semiconductor layer further includes a third surface region;
a fourth p-type semiconductor layer is disposed in the third surface region, the fourth p-type semiconductor layer having a higher p-type impurity concentration than the first p-type semiconductor layer; and
the second electrode is also disposed on the fourth p-type semiconductor layer.

5. The photodetector according to claim 1, wherein the photodiodes are arranged in an array.

6. The photodetector according to claim 2, further comprising
a quench resistor corresponding to the avalanche photodiode, the quench resistor being connected to the second electrode of the corresponding avalanche photodiode.

7. The photodetector according to claim 6, wherein the quench resistor is disposed around the corresponding avalanche photodiode.

8. The photodetector according to claim 1, further comprising
a power supply terminal,
wherein a reverse bias is applied between the first electrode and the second electrode of the photodiode via the power supply terminal.

9. The photodetector according to claim 1, further comprising:
a wave height detector configured to analyze a wave height of an electrical signal output from the photodiode; and
a signal processor configured to process a signal output from the wave height detector.

10. The photodetector according to claim 1, wherein:
the first p-type semiconductor layer has a p-type impurity concentration not lower than 1×10¹⁷ cm⁻³ and not higher than 1×10¹⁹ cm⁻³; and
the second p-type semiconductor layer has a p-type impurity concentration not lower than 1×10¹⁹ cm⁻³.

11. The photodetector according to claim 9, further comprising
scintillator configured to generate fluorescence from radiation,
wherein the photodiode converts the fluorescence output from the scintillator into an electrical signal.

12. A computed tomography device comprising;
the photodetector according to claim 11;
a radiation generating circuit configured to generate radiation;
a controller configured to control energy and timing of the radiation generated from the radiation generating circuit, and obtains synchronization with an output from the photodetector;
a data storage storing data output from the signal processor;
an image forming circuit configured to form an image in accordance with the data stored in the data storage; and
a display configured to display the image formed by the image forming circuit.

13. The device according to claim 12, wherein the photodiode is an avalanche photodiode.

14. The device according to claim 12, further comprising
a third p-type semiconductor layer disposed between the n-type semiconductor layer and the first p-type semiconductor layer, the third p-type semiconductor layer having a lower p-type impurity concentration than the second p-type semiconductor layer and having a higher p-type impurity concentration than the first p-type semiconductor layer.

15. The device according to claim 12, wherein;
the first p-type semiconductor layer further includes a third surface region;
a fourth p-type semiconductor layer is disposed in the third surface region, the fourth p-type semiconductor layer having a higher p-type impurity concentration than the first p-type semiconductor layer; and
the second electrode is also disposed on the fourth p-type semiconductor layer.

16. The device according to claim 12, wherein the photodiodes are arranged in an array.

17. The device according to claim 13, further comprising
a quench resistor corresponding to the avalanche photodiode, the quench resistor being connected to the second electrode of the corresponding avalanche photodiode.

18. The device according to claim 17, wherein the quench resistor is disposed around the corresponding avalanche photodiode.

19. The device according to claim 12, further comprising
a power supply terminal,
wherein a reverse bias is applied between the first electrode and the second electrode of the photodiode via the power supply terminal.

20. The photodetector according to claim 12, wherein:
the first p-type semiconductor layer has a p-type impurity concentration not lower than 1×10¹⁷ cm⁻³ and not higher than 1×10¹⁹ cm⁻³; and
the second p-type semiconductor layer has a p-type impurity concentration not lower than 1×10¹⁹ cm⁻³.
